(19) United States
(12) Patent Application Publication
(10) Pub. No.: US 2012/0244682 A1
(43) Pub. Date: Sep. 27, 2012

(54) WAFER DIVIDING METHOD

(75) Inventor: Kei Tanaka, Ota-ku (JP)

(73) Assignee: DISCO CORPORATION, Tokyo (JP)

(21) Appl. No.: 13/418,831

(22) Filed: Mar. 13, 2012

(30) Foreign Application Priority Data
Mar. 23, 2011 (JP) 2011-064591

(51) Int. Cl. H01L 21/78

(52) U.S. Cl. 438/464; 257/E21.599

(57) ABSTRACT

In a wafer dividing method, a wafer is held by a chuck table of a laser beam processing apparatus. A modified layer is formed by radiating a laser beam having a wavelength that transmits the laser beam through the wafer, while adjusting the beam convergence point to a position inside of the wafer, so as to form a pair of modified layers the interval of which is greater than the width of a cutting edge of a cutting blade and smaller than the width of planned dividing lines, on the back side of the wafer at both sides of each of the planned dividing lines. The wafer is adhered to a dicing tape and divided into individual devices by cutting along the dividing lines.

### BACKGROUND OF THE INVENTION

1. Field of the Invention

The present invention relates to a wafer dividing method by which a wafer such as a semiconductor wafer is divided along planned dividing lines.

2. Description of the Related Art

A semiconductor wafer formed on the face side thereof with a plurality of devices such as ICs, LSIs, etc., the individual devices being demarcated by planned dividing lines called streets formed in a grid pattern, is cut along the streets by a cutting apparatus to be thereby divided into the individual devices. The devices thus obtained upon the dividing process are widely used for various electric apparatuses such as cellular phones and personal computers. In the dividing process, the wafer is supported on an annular frame through a dicing tape therebetween, and the wafer in this state is mounted on a chuck table of a cutting apparatus. For the cutting of the wafer, a cutting apparatus called dicing saw is widely used which includes cutting means with a cutting blade supported in a rotatable manner.

The cutting blade has an annular cutting edge of 20 to 40 μm in thickness wherein super-abrasive grains of diamond, CBN (Cubic Boron Nitride) or the like are immobilized by a metal or resin. With the cutting edge positioned at the planned dividing line and with the cutting blade rotated at a high speed of about 30,000 rpm, cutting into the wafer is conducted and the chuck table is put into machining feed so as to cut the wafer in the manner of forming dividing grooves, whereby the wafer is divided into the individual devices.

### SUMMARY OF THE INVENTION

However, when a wafer is cut by a cutting blade along planned dividing lines to form diving grooves and thereafter the wafer is divided into individual devices, there arises a problem that comparatively large chip would occur on the back side of the wafer at both sides of the dividing groove, lowering the bending strength of the device. Such a problem may occur not only in such devices as ICs, LSIs, etc. but also in the cases of cutting devices not having any circuit, such as the case of cutting a quartz plate by a cutting blade to form a quartz resonator.

Accordingly, it is an object of the present invention to provide a wafer dividing method which is free of the problem of large chip on the back side of the wafer.

In accordance with an aspect of the present invention, there is provided a method of dividing a wafer having a plurality of devices formed on a face-side surface thereof in the state of being demarcated by planned dividing lines, into individual devices, the method including: a first holding step of holding the wafer by a chuck table of a laser beam processing apparatus; a modified layer forming step of radiating a laser beam of such a wavelength as to permit transmission of the laser beam through the wafer, while adjusting a beam convergence point to a position in the inside of the wafer, so as to form a pair of modified layers the interval of which is greater than the width of a cutting edge of a cutting blade and smaller than the width of the planned dividing lines, on the back side of the wafer at both sides of each of the planned dividing lines; a wafer adhering step of adhering the wafer to a dicing tape an outer circumferential portion of which is adhered to an annular frame; a second holding step of holding the wafer, after the modified layer forming step and the wafer adhering step are conducted, by a chuck table of a cutting apparatus through the dicing tape therebetween; and a dividing step of dividing the wafer into the individual devices by cutting each of the planned cutting lines by the cutting blade.

According to the wafer dividing method of the present invention, before carrying out the dividing step of dividing the wafer by the cutting blade into the individual devices, the modified layer forming step is conducted wherein a laser beam of such a wavelength as to permit transmission of the laser beam through the wafer is radiated to the wafer so that a pair of modified layers whose interval is greater than the width of the cutting edge of the cutting blade and smaller than the width of the planned dividing lines are formed on the back side of the wafer at both sides of each of the planned dividing lines. Therefore, a crushing force of the cutting edge is intercepted by the modified layers formed at both sides of each of the planned dividing lines, so that large chip at both sides of the dividing grooves formed on the back side of the wafer is prevented from occurring.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is an exploded perspective view showing the manner in which a protective tape is adhered onto the face-side surface of a semiconductor wafer;

FIG. 2 is an exploded perspective view showing the manner in which the side of the protective tape adhered to the face-side surface of the semiconductor wafer is suction held by a chuck table of a laser beam processing apparatus;

FIG. 3 is a perspective view illustrating a modified layer forming step;

FIG. 4 is a block diagram of a laser beam generating unit;

FIG. 5 is a perspective view of the semiconductor wafer supported on an annular frame through a dicing tape therebetween;

FIG. 6 is a perspective view showing the manner in which the semiconductor wafer is cut by a cutting blade; and

FIG. 7 is a vertical sectional view of the wafer at the time of cutting the wafer.

### DETAILED DESCRIPTION OF THE PREFERRED EMBODIMENT

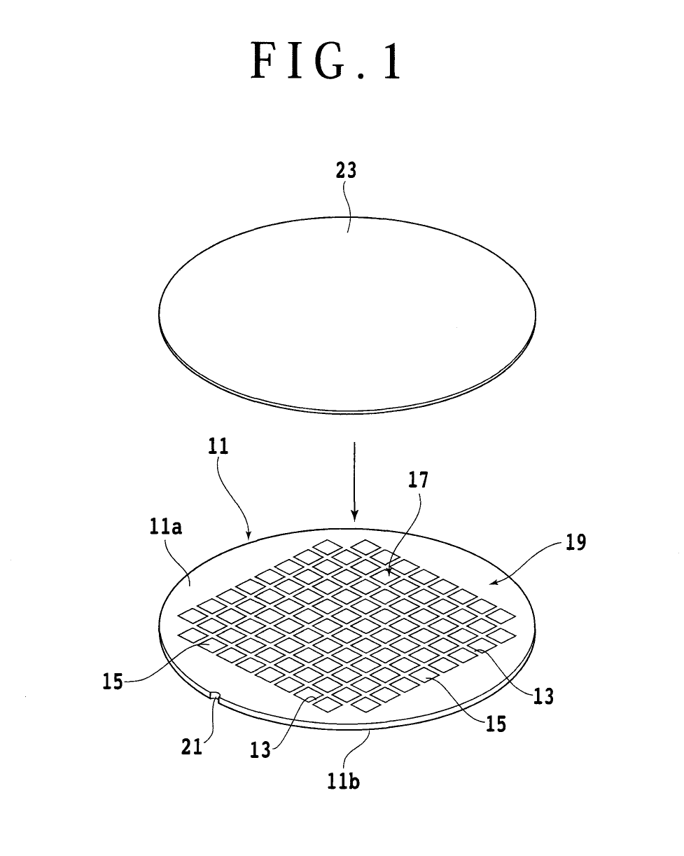

Now, an embodiment of the present invention will be described in detail below referring to the drawings. Referring to FIG. 1, there is shown an exploded perspective view illustrating the manner in which a protective tape 23 is adhered to a face-side surface 11a of a semiconductor wafer 11. The semiconductor wafer 11 is composed of a silicon wafer having a thickness of 700 μm, for example. On the face-side surface 11a, a plurality of planned dividing lines (streets) 13 are formed in a grid pattern, and devices 15 such as ICs and LSIs are formed respectively in the regions demarcated by the plurality of planned dividing lines 13. The wafer 11 thus configured is provided with a device region 17 in which the devices 15 are formed, and an outer circumferential marginal region 19 surrounding the device region 17. In addition, the outer circumference of the wafer 11 is formed with a notch 21 as a mark indicative of the crystal orientation of the silicone wafer.

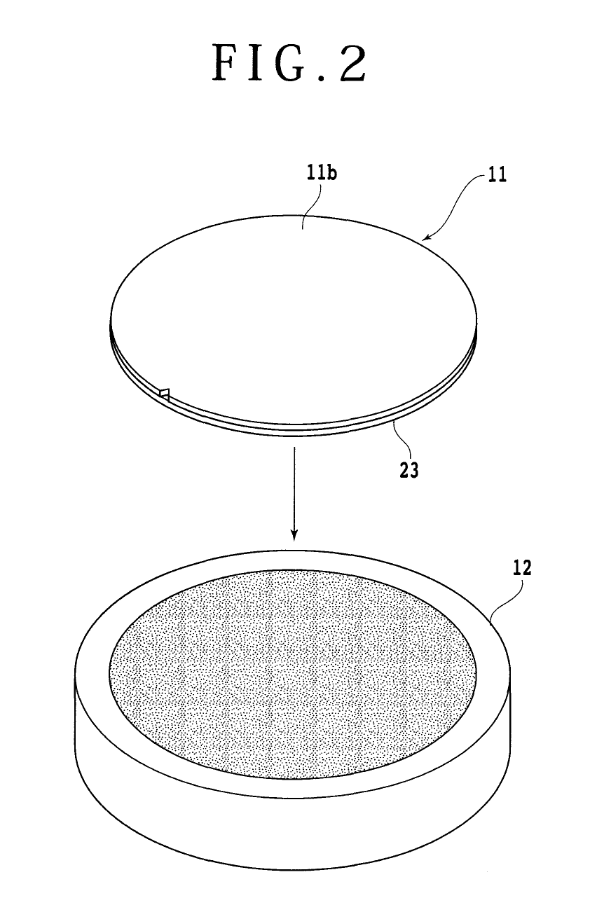

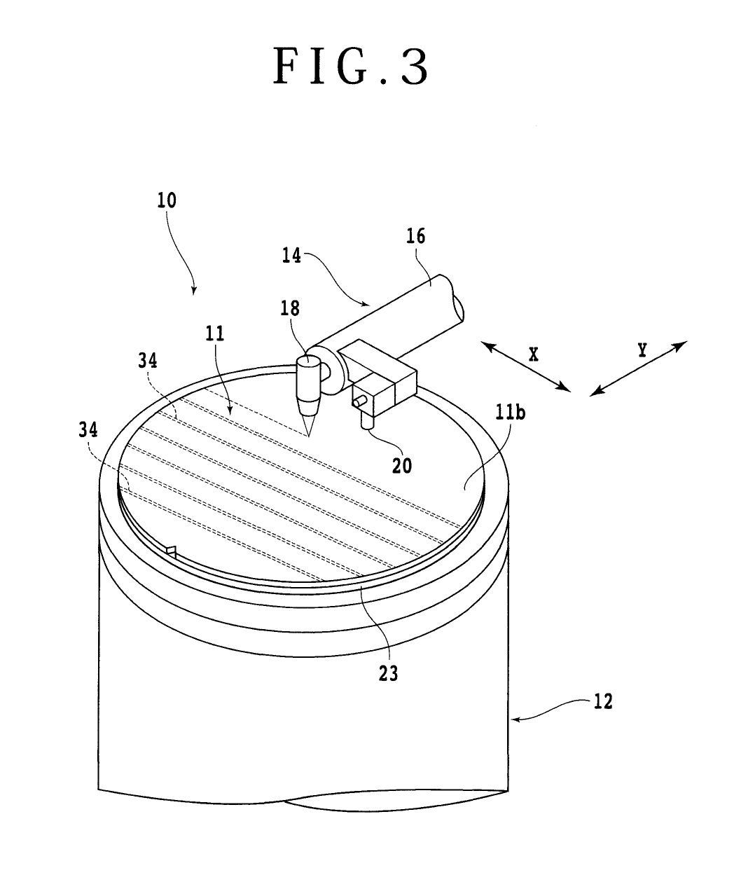

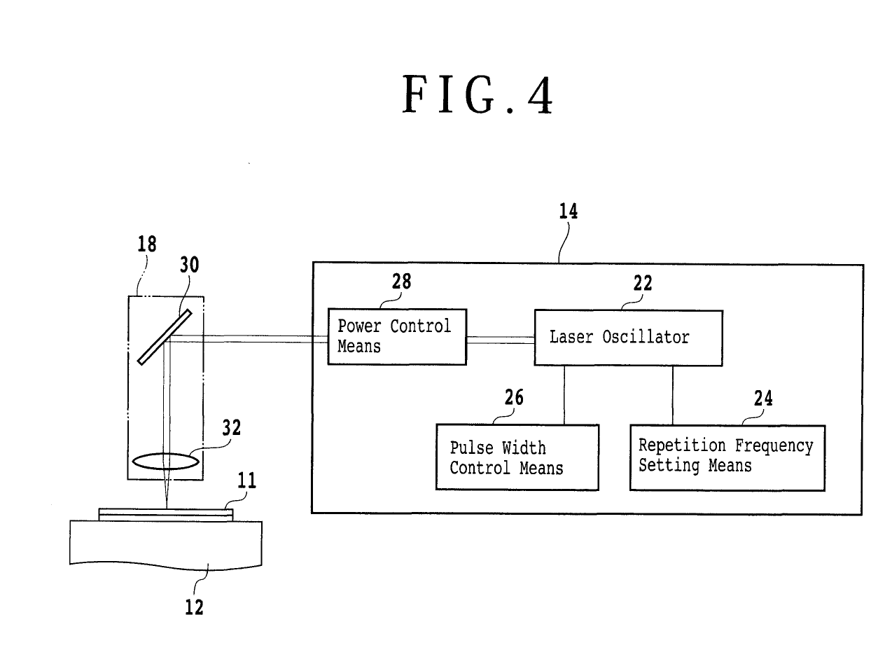

In the wafer dividing method according to the present invention, in order to protect the devices 15 formed at the face-side surface 11a of the wafer 11, the protective tape 23 is adhered to the face-side surface 11a of the wafer 11, as shown in FIG. 1. Next, as shown in FIG. 2, the wafer 11 is suction held, with the protective tape 23 side down, by a chuck table 12 of a laser beam processing apparatus. This results in that the back surface 11b of the wafer 11 is exposed. With the back surface 11b of the wafer 11 thus exposed, the wafer 11 is suction held by the chuck table 12 of the laser beam processing apparatus, and a modified layer forming step is conducted in which modified layers are formed in the inside of the wafer 11. The modified layer forming step will be described in detail, referring to FIGS. 3 and 4.

FIG. 3 shows a perspective view of a major part of the laser beam processing apparatus 10. On the chuck table 12, the wafer 11 with the protective tape 23 adhered onto the face-side surface 11a thereof is suction held, with the back surface 11b up. Reference symbol 14 denotes a laser beam generating unit, which has a configuration wherein a laser oscillator 22, repetition frequency setting means 24, pulse width control means 26, and power control means 28 are contained in a housing 16, as shown in FIG. 4. A laser beam controlled to a predetermined power by the power control means 28 of the laser beam generating unit 14 is reflected by a mirror 30 of a condenser (laser irradiation head) 18 and radiated while being converged by a condenser lens 32 into a position in the inside of the wafer 11, whereby modified layers 34 are formed in the inside of the wafer 11.

At a tip portion of the housing 16, imaging means 20 for detecting a processing region to be processed by a laser beam is disposed in line with the condenser 18 in the X-axis direction. The imaging means 20 includes an imaging element, such as an ordinary CCD, for imaging the processing region of the semiconductor wafer 11 by use of visible light. The imaging means 20 further includes infrared irradiation means for radiating an infrared ray to the semiconductor wafer 11, an optical system for capturing the infrared ray radiated by the infrared irradiation means, and infrared imaging means including an infrared imaging element such as an infrared CCD for outputting an electrical signal corresponding to the infrared ray captured by the optical system. An image signal obtained upon the imaging is transmitted to a controller in the laser beam processing apparatus 10.

In carrying out the modified layer forming step, a planned dividing line 13 extending in a first direction to be processed on the side of the face-side surface 11a of the wafer 11 is imaged by the infrared imaging element of the imaging means 20, and alignment for aligning the condenser 18 and the planned dividing line 13 to be processed by a laser beam is carried out. Further, after rotating the chuck table 12 by 90 degrees, a planned dividing line 13 extending in a second direction orthogonal to the first direction is imaged by the infrared imaging element of the imaging means 20, and alignment for aligning the condenser 18 and the planned dividing line 13 extending in the second direction is carried out.

After the alignment, a laser beam with such a wavelength as to permit transmission of the laser beam through the wafer 11 is radiated while adjusting the beam convergence point to a position in the vicinity of the back surface 11b of the wafer 11, and, while putting the chuck table 12 into machining feed along the X-axis direction, a pair of modified layers 34 whose interval is greater than the width of a cutting edge of a cutting blade (to be used later) and smaller than the width of the planned dividing line 13 are formed at both sides of the planned dividing line 13 and in the vicinity of the back surface 11b of the wafer 11. Formation of the pair of modified layers 34 is conducted for every one of the planned dividing lines 13 extending in the first direction. Subsequently, the chuck table 12 is rotated by 90 degrees, and thereafter formation of the pair of modified layers 34 is performed for every one of the planned dividing lines 13 extending in the second direction orthogonal to the first direction.

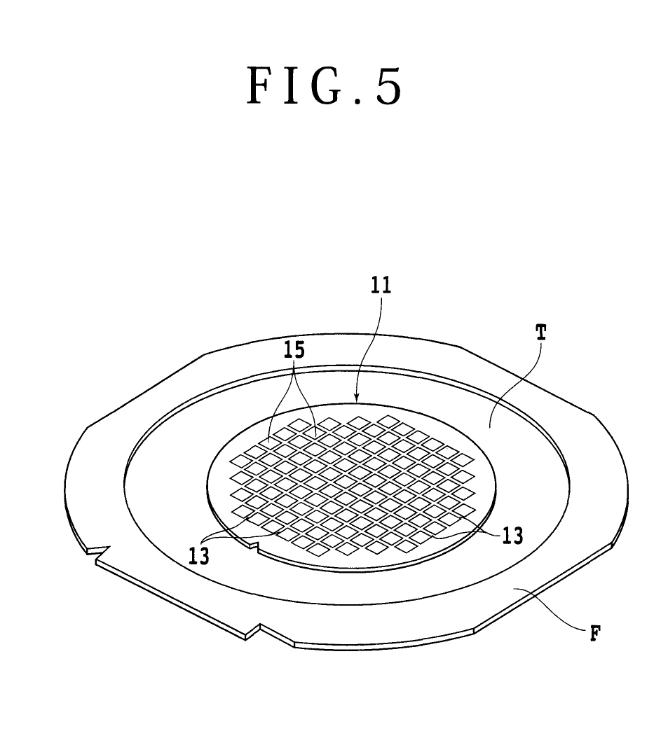

While the laser beam is radiated from the side of the back surface 11b of the wafer 11 in the above-described embodiment, the laser beam may be radiated from the side of the face-side surface 11a so as to form the modified layers in the vicinity of the back surface 11b of the wafer 11. In this case, it is not necessary that the protective tape 23 for protecting the devices 15 on the wafer 11 is adhered to the face-side surface 11a of the wafer 11, and the wafer 11 is suction held directly by the chuck table 12 of the laser beam processing apparatus 10. Or, in the condition where the wafer 11 is supported by an annular frame F through a dicing tape T therebetween as shown in FIG. 5, the wafer 11 is suction held by the chuck table 12 through the dicing tape T therebetween.

The process conditions in the modified layer forming step are, for example, as follows.

Light source: LD-pumped Q-switch Nd: YVO4 laser

Wavelength: 1064 nm

Mean output: 1 W

Pulse width: 40 ns

Convergent spot diameter: φ1 μm

Repetition frequency: 100 kHz

Feed rate: 100 mm/s

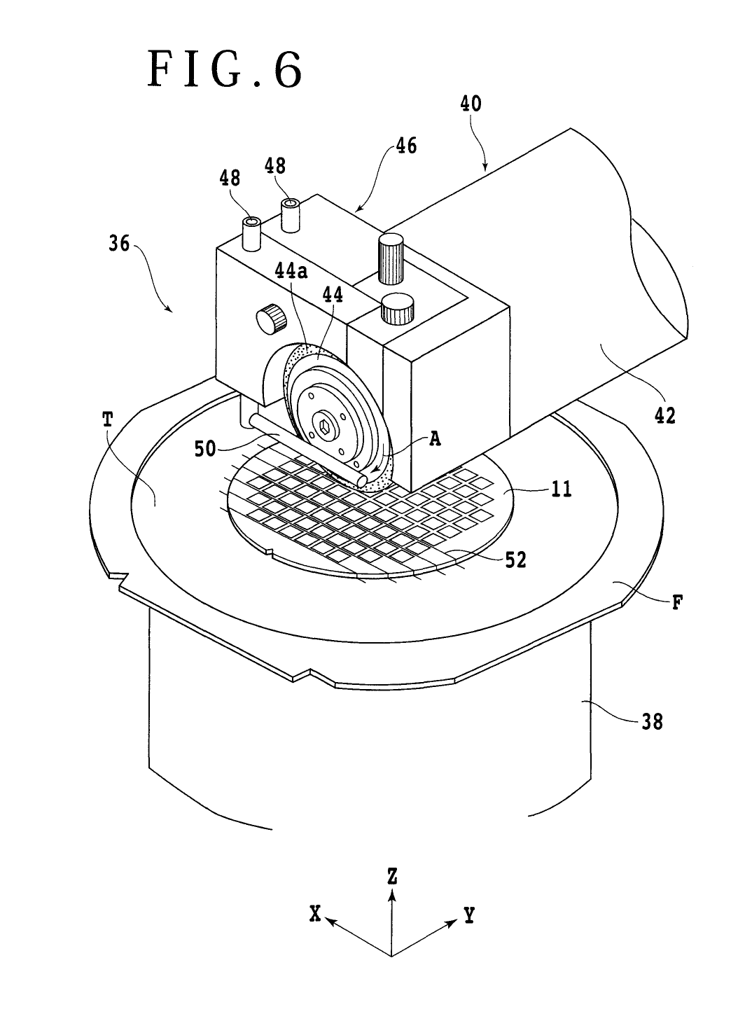

After the modified layer forming step, the wafer 11 formed with the modified layers 34 is adhered to the dicing tape T whose outer circumferential portion is adhered to the annular frame F, as shown in FIG. 5, whereby the wafer 11 is supported on the annular frame F through the dicing tape T therebetween. Then, the protective tape 23 is peeled from the face-side surface 11a of the wafer 11. A supporting step of supporting the wafer 11 by the annular frame F with the dicing tape T therebetween may be carried out before the modified layer forming step. After the wafer 11 is thus supported by the annular frame F through the dicing tape T therebetween, the wafer 11 is suction held by a chuck table 38 of a cutting apparatus 36, through the dicing tape T therebetween, as shown in FIG. 6.

In FIG. 6, reference symbol 40 denotes a cutting unit of the cutting apparatus 36. The cutting unit includes a spindle rotary driven by a motor (not shown) contained in a spindle housing 42, and a cutting blade 44 detachably attached to the tip of the spindle. The cutting blade 44 is covered by a wheel cover 46, and pipes 48 on the wheel cover 46 are connected to a cutting water supply source. The cutting blade 44 has a configuration wherein a cutting edge (grinding wheel portion) 44a having diamond abrasive grains dispersed in a nickel matrix or a nickel alloy matrix is electrodeposited on the outer circumference of a circular base.

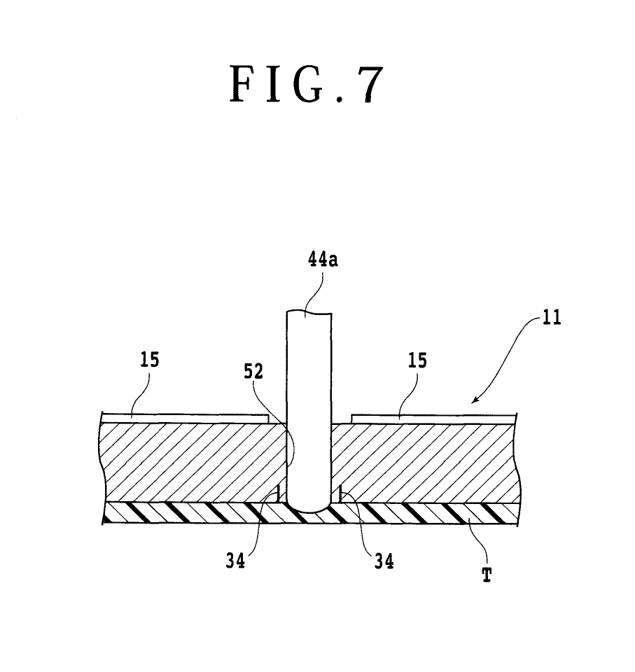

At the time of cutting the wafer 11, while cutting water is jetted from a cutting water nozzle 50 and the cutting blade 44 is rotated at a high speed (for example, 30,000 rpm) in the direction of arrow A, the chuck table 38 is put into machining feed along the X-axis direction. By this operation, as shown in FIG. 7, the wafer 11 is cut along the planned dividing line 13, resulting in that a cut groove (dividing groove) 52 is formed. Since the pair of modified layers 34 have been formed in the vicinity of the back surface 11b of the wafer 11 at both sides of each of the planned dividing line 13 in the modified layer forming step, the crushing force of the cutting edge 44a is intercepted by the modified layers 34, so that large chip is prevented from being generated on the back surface 11b of the wafer 11 at both sides of the dividing groove 52. After every one of the planned dividing lines 13 extending in the first direction is cut by the cutting blade 44, the chuck table 38 is rotated by 90 degrees, and similar cutting is carried out also for every one of the planned dividing lines 13 extending in the second direction orthogonal to the first direction. In this manner, the wafer 11 is divided into the individual devices 15.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of dividing a wafer having a plurality of devices formed on a face-side surface thereof in the state of being demarcated by planned dividing lines, into individual devices, the method comprising:
a first holding step of holding the wafer by a chuck table of a laser beam processing apparatus;
a modified layer forming step of radiating a laser beam of such a wavelength as to permit transmission of the laser beam through the wafer, while adjusting a beam convergence point to a position in an inside of the wafer, so as to form a pair of modified layers an interval of which is greater than a width of a cutting edge of a cutting blade and smaller than a width of the planned dividing lines, on a back side of the wafer at both sides of each of the planned dividing lines;
a wafer adhering step of adhering the wafer to a dicing tape an outer circumferential portion of which is adhered to an annular frame;
a second holding step of holding the wafer, after the modified layer forming step and the wafer adhering step are conducted, by a chuck table of a cutting apparatus through the dicing tape therebetween; and
a dividing step of dividing the wafer into the individual devices by cutting each of the planned cutting lines by the cutting blade.
